(19) United States
(12) Patent Application Publication
(10) Pub. No.: US 2006/0197436 A1
(43) Pub. Date: Sep. 7, 2006

(54) ZnO nanotip electrode electroluminescence device on silicon substrate

(75) Inventors: John F. Conley JR., Camas, WA (US); Yoshi Ono, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/240,970

(22) Filed: Sep. 30, 2005

Related U.S. Application Data
(63) Continuation-in-part of application No. 11/070,051, filed on Mar. 1, 2005.

(51) Int. Cl. H01L 51/00; H05B 33/00

(52) U.S. Cl. 313/498; 257/40

(57) ABSTRACT

A device and a fabrication method are provided for a ZnO nanotip electroluminescence (EL) device on a silicon (Si) substrate. The method includes: forming a Si substrate; forming a bottom contact overlying the Si substrate; forming a seed layer overlying the bottom contact; forming ZnO nanotips with tops, overlying the seed layer; forming an insulating film overlying the ZnO nanotips; etching the insulating film; exposing the ZnO nanotip tops; and, forming a transparent top electrode overlying the exposed ZnO nanotip tops. In one aspect, after forming the ZnO nanotips, an ALD process can be used to coat the ZnO nanotips with a material such as Al₂O₃ or HfO₂. The seed layer can be ZnO or ZnO:Al, formed using a deposition process such as sputtering, chemical vapor deposition (CVD), spin-on, or atomic layer deposition (ALD).

### RELATED APPLICATIONS

This application is a Continuation-in-Part of a pending patent application entitled, NANOTIP ELECTRODE ELECTROLUMINESCENCE DEVICE WITH CONTOURED PHOSPHOR LAYER, invented by Conley et al., Ser. No. 11/070,051, filed on Mar. 1, 2005. This application claims priority to the above-mentioned parent application under 35 U.S.C. 120, and expressly incorporates the parent application by reference.

### BACKGROUND OF THE INVENTION

1. Field of the Invention

This invention generally relates to integrated circuit (IC) fabrication and, more particularly, to a ZnO nanotip electroluminescence (EL) device formed on a silicon (Si) substrate.

2. Description of the Related Art

The generation of light from semiconductor devices is possible, regardless of whether the semiconductor material forms a direct or indirect bandgap. High field reverse biased p-n junctions create large hot carrier populations that recombine with the release of photons. For silicon devices, the light generation efficiency is known to be poor and the photon energy is predominantly around 2 eV. The conversion of electrical energy to optical photonic energy is called electroluminescence (EL). Efficient EL devices have been made that can operate with small electrical signals, at room temperature. However, these devices are fabricated on materials that are typically not compatible with silicon, for example type III-V materials such as InGaN, AlGaAs, GaAsP, GaN, and GaP. An EL device built on one of these substrates can efficiently emit light in a narrow bandwidth within the visible region, depending on the specific material used. Additionally, type II-VI materials such as ZnSe have been used. Other type II-VI materials such as ZnS and ZnO are known to exhibit electroluminescence under ac bias conditions. These devices can be deposited onto silicon for use in light generating devices if special (non-conventional) CMOS processes are performed. Other classes of light emitting materials are organic light emitting diodes (OLEDs), nanocrystalline silicon (nc-Si), and polymer LEDs.

Silicon has conventionally been considered unsuitable for optoelectronic applications, due to the indirect nature of its energy band gap. Bulk silicon is indeed a highly inefficient light emitter. Among the different approaches developed to overcome this problem, quantum confinement in Si nanostructures and rare earth doping of crystalline silicon have received a great deal of attention.

A simple and efficient light-emitting device compatible with silicon would be desirable in applications where photonic devices (light emitting and light detecting) are necessary. Efficient silicon substrate EL devices would enable a faster and more reliable means of signal coupling, as compared with conventional metallization processes. Further, for intra-chip connections on large system-on-chip type of devices, the routing of signals by optical means is also desirable. For inter-chip communications, waveguides or direct optical coupling between separate silicon pieces would enable packaging without electrical contacts between chips. For miniature displays, a method for generating small point sources of visible light would enable simple, inexpensive displays to be formed.

FIG. 1 is a partial cross-sectional view of a thin-film, solid-state Si phosphor EL device (prior art). EL devices compatible with Si are currently being sought for a number of applications such as optical interconnects. An AC EL device may consist of a substrate 1, an optional bottom electrode 2, a phosphor layer 4, sandwiched by a top 5 and bottom 3 dielectric layer, and a top transparent electrode 6. Such a device typically requires high operating fields in order to inject electrons from states at the interface into the phosphor layer. The electrons are then, accelerated by the field, gaining energy until they radiatively decay at luminescent centers.

Nanostructured materials such as nanowires, nanorods, and nanoparticles, have potential for use in applications such as nanowire chemical and bio sensors, nanowire LEDs, nanowire transistors, nanowire lasers, to name a few examples. Materials such as Si, Ge, other elemental semiconductors, ZnO, and other binary semiconductors have been made into nanostructures. One of the primary methods for nanowire formation is the vapor-liquid solid transport method with which a catalyst can be used to grow a nanowire from the gas phase. Other methods have also been used.

ZnO is another photo-luminescent (PL) material of interest that exhibits an intrinsic UV PL at 380 nanometers (nm) and a defect-related visible PL broadly centered around about 500-700 nm. A ZnO EL device structure on Si would be desirable in order to take advantage of widely-used CMOS control electronics.

An often reported technique for incorporating nanostructures into CMOS electronics involves growing nanowires on one substrate, “harvesting” them, and then dispersing them onto the device substrate, which is often referred to as the “pick and place” method. The use of nanostructures grown directly onto the device substrate is still not widely reported. Fabrication of devices using directly grown nanowires has advantages over more conventional pick and place methods, such as cleanliness and direct placement of nanostructures.

### SUMMARY OF THE INVENTION

The present invention provides a method for fabricating a ZnO nanotip-based EL device on a Si substrate. As an alternate to conventional processes, ZnO nanotips are embedded in an insulator material, but the end of ZnO nanotips are exposed. The exposed nanotips ends (tops) form a better electrical contact with overlying p-type material, or a transparent electrode material.

Accordingly, a method is provided for fabricating a ZnO nanotip electroluminescence (EL) device on a silicon (Si) substrate. The method comprises: forming a Si substrate; forming a bottom contact overlying the Si substrate; forming a seed layer overlying the bottom contact; forming ZnO nanotips with tops, overlying the seed layer; forming an insulating film overlying the ZnO nanotips; etching the insulating film; exposing the ZnO nanotip tops; and, forming a transparent top electrode overlying the exposed ZnO nanotip tops. In one aspect, after forming the ZnO nanotips, an ALD process can be used to coat the ZnO nanotips with a material such as Al₂O₃ or HfO₂.

The seed layer can be ZnO or ZnO:Al, formed using a deposition process such as sputtering, chemical vapor deposition (CVD), spin-on, or atomic layer deposition (ALD). The insulating film overlying the ZnO nanotips can be either spin-on polystyrene or polymers, for example, which can be etched using an O₃ plasma. Alternately, the insulating film is spin-on glass (SOG), which can be wet or dry etched.

In one aspect, the bottom contact is a result of implanting an n+ dopant in the Si substrate, forming an n+ layer of Si substrate. In another aspect, both the bottom contact and the seed layer are formed from a ZnO:Al layer overlying the Si substrate.

Additional details of the above-described method, and a ZnO nanotip EL device on Si substrate, are provided below.

### BRIEF DESCRIPTION OF THE DRAWINGS

FIG. 1 is a partial cross-sectional view of a thin-film, solid-state Si phosphor EL device (prior art).

FIG. 2 is a partial cross-sectional view of a ZnO nanotip electroluminescence (EL) device on silicon (Si) substrate.

FIG. 3 is a partial cross-sectional view of a first variation of the ZnO nanotip EL device of FIG. 2.

FIG. 4 is a partial cross-sectional view of a second variation of the ZnO nanotip EL device of FIG. 2.

FIG. 5 is a partial cross-sectional view of a third variation of the ZnO nanotip EL device of FIG. 2.

FIGS. 6 through 11 depicts steps in a process for fabricating a ZnO nanotip-based EL device structure on a Si substrate.

FIGS. 12 through 14 depict steps in a variation of the fabrication process of FIGS. 6 through 11.

FIG. 15 is a flowchart illustrating a method for fabricating a ZnO nanotip EL device on a Si substrate.

### DETAILED DESCRIPTION

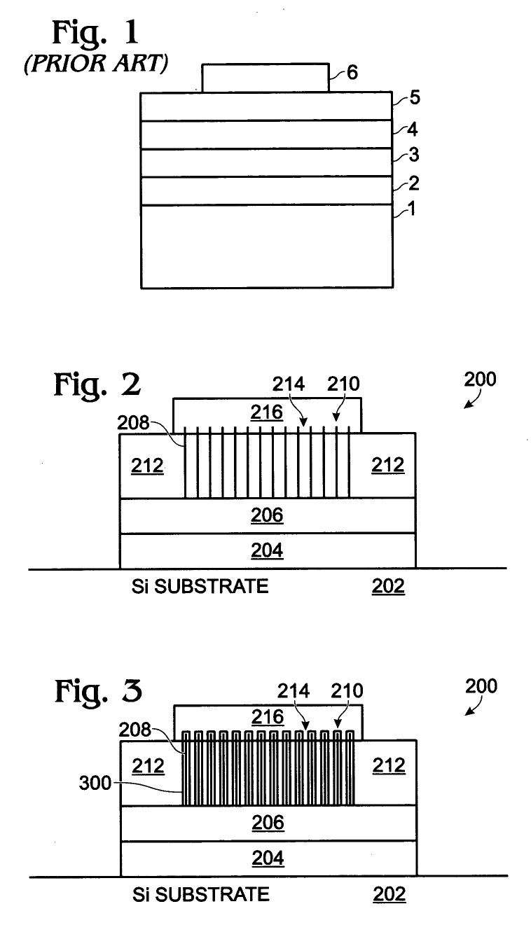

FIG. 2 is a partial cross-sectional view of a ZnO nanotip electroluminescence (EL) device on silicon (Si) substrate. The EL device 200 comprises a Si substrate 202, and a bottom contact 204 overlying the Si substrate 202. A seed layer 206 overlies the bottom contact 204. Typically, the seed layer 206 is a ZnO or ZnO:Al material. ZnO nanotips 208 with tops 210, overlie the seed layer 206. An insulating film 212 overlies the ZnO nanotips 208. The insulating film 212 has a top surface 214 with exposed ZnO nanotip tops 210. The insulating film 212 may be spin-on polystyrene, spin-on glass, or polymer material. A transparent top electrode 216 overlies the exposed ZnO nanotip tops 210. The transparent electrode 216 may be a material such as Indium Tin Oxide (ITO), ZnO:Al, or Au. In another aspect, the bottom contact 204 and the seed layer 206 are both a ZnO:Al layer overlying the Si substrate 202. In one aspect, as shown, the bottom contact 204 includes an n+ layer of Si overlying the Si substrate.

FIG. 3 is a partial cross-sectional view of a first variation of the ZnO nanotip EL device of FIG. 2. In this aspect, there is a coating 300 over the ZnO nanotips 208. The coating 300 may be Al₂O₃ or HfO₂, for example.

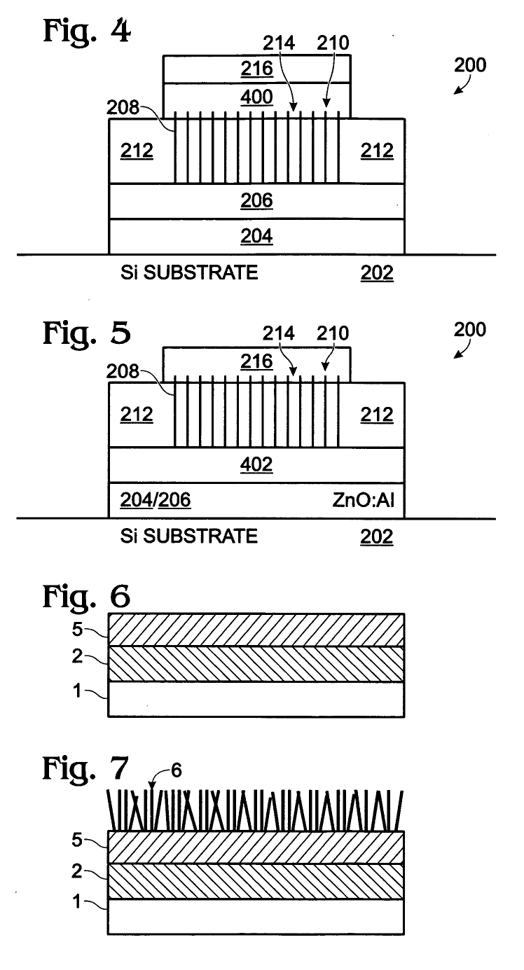

FIG. 4 is a partial cross-sectional view of a second variation of the ZnO nanotip EL device of FIG. 2. A p-type material 400 is interposed between the exposed ZnO nanotip tops 210 and the transparent electrode 216. The p-material can be poly(3,4-ethylenedioxythiophene) (PEDOT), SrCuO, Cu2O, ZnO:N, ZnO:As, or ZnO:P.

FIG. 5 is a partial cross-sectional view of a third variation of the ZnO nanotip EL device of FIG. 2. In another aspect, the bottom contact 204 and the seed layer 206 are both a ZnO:Al layer overlying the Si substrate 202. In this aspect, an insulator 402 may optionally be interposed between the ZnO:Al layer 204/206 and the ZnO nanotips 208. Insulator 402 may be a material such as Al₂O₃ or HfO₂.

As used herein, the word “nanotip” is not intended to be limited to any particular physical characteristics, shapes, or dimensions. The nanotips may alternately be known as nanorods, nanotubes, or nanowires. In some aspects (not shown), the nanotips may form a hollow structure. In other aspects (not shown), the nanotips may be formed with a plurality of tips ends.

### Functional Description

FIGS. 6 through 11 depicts steps in a method for fabricating a ZnO nanotip based EL device structure on a Si substrate. As shown in FIG. 6, the fabrication of the nanotip EL device begins with a clean Si substrate, layer (1). An n-type Si substrate is shown. The first step is to implant an n-type dopant to form an n+ well, layer (2). The purpose of this step is to improve the electrical contact between the substrate and the device.

Next a thin seed layer (i.e., ZnO) (5) is deposited. The ZnO can be deposited by any state of the art method. In this case, ZnO is deposited via atomic layer deposition. The ZnO layer can be annealed at high temperature (about 300-900° C.) before proceeding to the next step. This layer serves as a seed for selective ZnO nanowire (NW) growth. This seed layer may be patterned by lithography and etching, with HF for example, before proceeding to next step. Selective etching is useful in forming an addressable array of devices accessed by individual electrodes, or a pattern of light emitting areas accessed by a single top electrode.

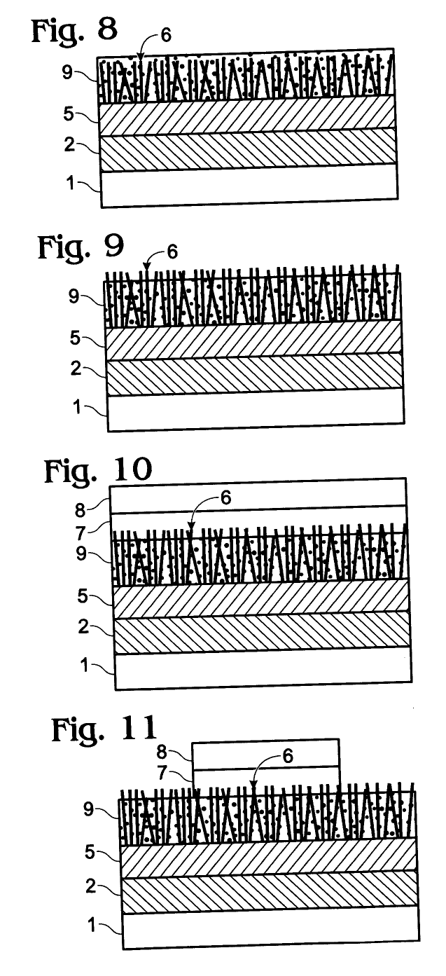

In FIG. 7, ZnO nanotips (6) are grown. In this case at 915° C. using a vapor-solid mechanism, where Zn vapor precursor is supplied from a mixture of graphite and ZnO power through carbo-thermal reduction of the ZnO. ZnO nanotips grow wherever the thin film of ZnO is present. Alternately, any method of forming the ZnO nanotips can be used. Evaporation of Zn metal, electrodeposition at 80° C. using ZnCl₂ and KCl, and solution-solid deposition using Zn metal in a formamide solution at 60° C. are all alternate means of forming ZnO nanotips.

In FIG. 8, a layer of insulating film (9) is placed around the nanotips. One method is to use spin-on polystyrene. Alternately, other polymers could also be used. For silicon-based devices with sensitivity to higher temperatures, a spin-on glass can be used to accomplish the same purpose as long as the correct viscosity and spin coat conditions are chosen.

In another alternate aspect, the nanotips are first coated with a conformal thin ALD (such as HfO₂, Al₂O₃, etc.) film prior to polystyrene deposition in order protect the nanotips from the subsequent etching step. As ZnO is extremely vulnerable to etching, this coating step is valuable, but not necessary, in the case of the SOG coating.

Next (FIG. 9), in order to expose the tops of the ZnO nanotips, the polystyrene or polymer film is briefly exposed to an O₃ plasma in order to gently etchback the material. In the case of the SOG-covered nanowires, the SOG film can be either selectively wet or dry etched in order to expose the tips. In order to minimize any potential damage to the ZnO nanowires, this etch step may be performed on ALD Al2O3 or HfO2-coated ZnO nanowires.

In order to establish a top contact to the nanotips, a PEDOT layer (7) may be optionally deposited, followed by a transparent electrode (8) of thin Au, ITO, ZnO:Al, or similar materials, see FIG. 10.

In FIG. 11, layers (7) and (8) are patterned and etched in order to form a device. Contact is made from the substrate (1) to the top contact (8).

FIGS. 12 through 14 depict steps in a variation of the fabrication process of FIGS. 6 through 11. In an alternative aspect, the bottom contact, layer (3), is deposited after implanting layer (2). The purpose of layer (3) is to improve contact to the device. In this case it is ALD deposited ZnO:Al. This bottom contact layer must be able to withstand subsequent high temperature processing. Following the deposition of layer (3), fabrication proceeds with deposition of layer (5), see FIG. 12.

Alternately (FIG. 13), layer 3 can be used as a bottom contact. In this case, fabrication proceeds with deposition of layer (5). Layer (5) is then patterned and etched, and fabrication proceeds with the growth of the ZnO nanotips (6). Finally, layers (7) and (8) are patterned and etched.

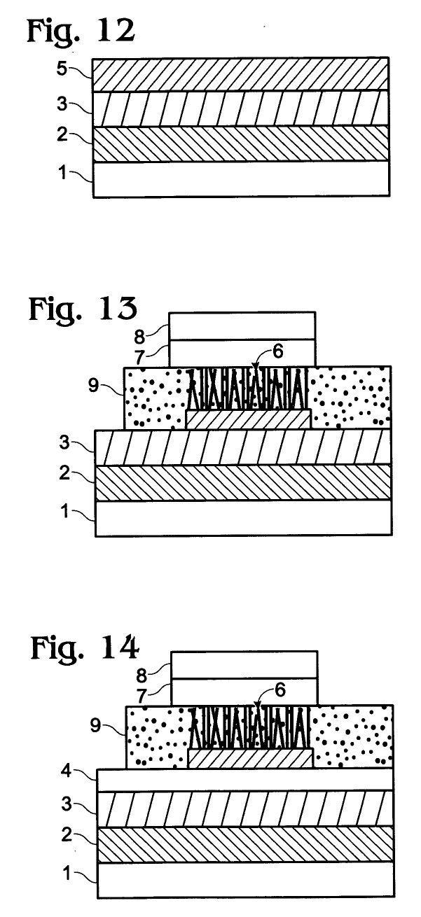

In another alternate aspect, see FIG. 14, an insulating layer (4) is deposited between layers (3) and (5). The purpose of this insulating layer is to limit current through the device. In this case, either ALD Al₂O₃ or ALD HfO₂ could be used. In principle, any insulator can be deposited using any method. The specific choice of insulator and method may allow for optimization of device operation.

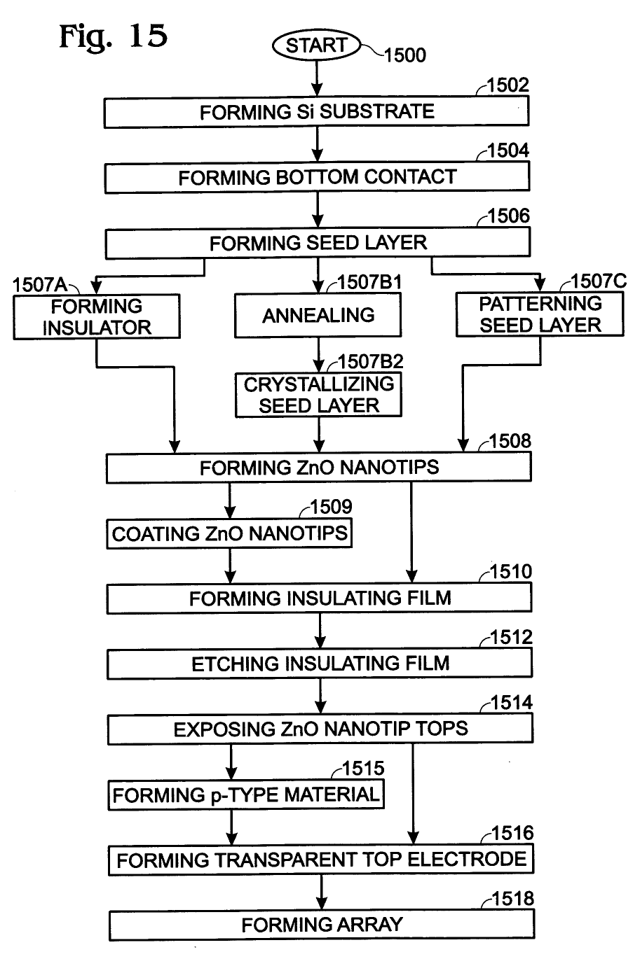

FIG. 15 is a flowchart illustrating a method for fabricating a ZnO nanotip EL device on a Si substrate. Although the method is depicted as a sequence of numbered steps for clarity, the ordering of the steps does not necessarily follow the numbering. It should be understood that some of these steps may be skipped, performed in parallel, or performed without the requirement of maintaining a strict order of sequence. Some details of the method may be better understood in context of the explanations of FIGS. 2-14, above. The method starts at Step 1500.

Step 1502 forms a Si substrate. Step 1504 forms a bottom contact overlying the Si substrate. Step 1506 forms a seed layer overlying the bottom contact. Step 1508 forms ZnO nanotips with tops, overlying the seed layer. Step 1510 forms an insulating film overlying the ZnO nanotips. Step 1512 etches the insulating film. Step 1514 exposes the ZnO nanotip tops. Step 1516 forms a transparent top electrode overlying the exposed ZnO nanotip tops. The top electrode can be made from a thin layer of ITO, ZnO:Al, or Au. However, other materials are also possible.

In one aspect, forming the bottom contact in Step 1504 includes implanting an n+ dopant in the Si substrate, forming an n+ layer of Si substrate. Alternately, Steps 1504 and 1506 of forming the bottom contact and the seed layer, respectively, includes forming both layers from a ZnO:Al layer overlying the Si substrate. That is, Steps 1504 and 1506 are combined if ZnO:Al is used. Then, Step 1507A uses an ALD process to form an insulator interposed between the ZnO:Al seed layer and the ZnO nanotips, from a material such as Al₂O₃ or HfO₂.

Typically, the seed layer of Step 1506 is either ZnO or ZnO:Al. The seed layer can be formed using a deposition process such as sputtering, chemical vapor deposition (CVD), spin-on, or ALD. In one aspect, Step 1507B1 anneals after forming the seed layer, and Step 1507B2 crystallizes the structure of the seed layer in response to the annealing.

In another aspect, forming ZnO nanotips in Step 1508 includes substeps (not shown). Step 1508A introduces a mixture of graphite and Zn powder. Step 1508B heats the substrate to a temperature of about 915° C. Step 1508C grows ZnO nanotips using a vapor-solid mechanism. Alternately, ZnO nanotips can be formed using another vapor solid growth, where Zn vapor is supplied from evaporating a Zn metal at an elevated temperature, electrodeposition of a solution including ZnCl₂ and KCl at a temperature of about 80° C., or solid-solution deposition using a Zn metal source in a 60° C. formamide solution. In one aspect, after forming the ZnO nanotips in Step 1508, Step 1509 uses an ALD process to form a coating over the ZnO nanotips, from a material such as Al₂O₃ or HfO₂.

Forming the insulating film overlying the ZnO nanotips in Step 1510 may include using a material such as a spin-on polystyrene or a polymer. Then, etching the insulating film in Step 1512 includes etching the insulating film using an O₃ plasma. Alternately, Step 1510 forms the insulating film from spin-on glass (SOG), and Step 1512 etches the SOG using either a wet or dry etch.

In one aspect an additional step, Step 1515, forms a p-type material interposed between the exposed ZnO nanotip tops and the transparent electrode. Some suitable p-type materials include poly(3,4-ethylenedioxythiophene (PEDOT), SrCuO, Cu2O, ZnO:N, ZnO:As, and ZnO:P.

In another aspect, Step 1507C patterns the seed layer, exposing selected regions of the seed layer, after forming the seed layer in Step 1506. Then, forming the ZnO nanotips in Step 1508 includes forming ZnO nanotips overlying the exposed regions of the seed layer. A further step, Step 1518, forms an array of ZnO nanotip EL devices connected to a common bottom contact.

A ZnO nanotip EL device on a Si substrate, and a corresponding fabrication process have been provided. Specific materials and fabrication details have been given as examples to help illustrate the invention. However, the invention is not limited to merely these examples. Other variations and embodiments of the invention will occur to those skilled in the art.

We claim:

1. A method for fabricating a ZnO nanotip electroluminescence (EL) device on a silicon (Si) substrate, the method comprising:
forming a Si substrate;
forming a bottom contact overlying the Si substrate;
forming a seed layer overlying the bottom contact;
forming ZnO nanotips with tops, overlying the seed layer;
forming an insulating film overlying the ZnO nanotips;
etching the insulating film;
exposing the ZnO nanotip tops; and,
forming a transparent top electrode overlying the exposed ZnO nanotip tops.

2. The method of claim 1 wherein forming the bottom contact includes implanting an n+ dopant in the Si substrate, forming an n+ layer of Si substrate.

3. The method of claim 1 wherein forming the seed layer includes forming the seed layer from a material selected from the group consisting of ZnO and ZnO:Al.

4. The method of claim 3 wherein forming the seed layer overlying the bottom contact includes forming the seed layer using a deposition process selected from the group consisting of sputtering, chemical vapor deposition (CVD), spin-on, and atomic layer deposition (ALD).

5. The method of claim 1 further comprising:
after forming the seed layer, patterning the seed layer, exposing selected regions of the seed layer;
wherein forming the ZnO nanotips includes forming ZnO nanotips overlying the exposed regions of the seed layer; and,
the method further comprising:
forming an array of ZnO nanotip EL devices connected to a common bottom contact.

6. The method of claim 1 further comprising:
after forming the seed layer, annealing;
in response to the annealing, crystallizing the structure of the seed layer.

7. The method of claim 1 wherein forming ZnO nanotips includes:
introducing a mixture of graphite and Zn powder;
heating the substrate to a temperature of about 915° C.;
growing ZnO nanotips using a vapor-solid mechanism.

8. The method of claim 1 wherein forming ZnO nanotips includes using a process selected from the group consisting of:
vapor solid growth where Zn vapor is supplied from evaporating a Zn metal at an elevated temperature;
electrodeposition of a solution including ZnCl₂ and KCl at a temperature of about 80° C.; and,
solid-solution deposition using a Zn metal source in a 60° C. formamide solution.

9. The method of claim 1 further comprising:
after forming the ZnO nanotips, using an ALD process to form a coating over the ZnO nanotips, selected from the group consisting of Al₂O₃ and HfO₂.

10. The method of claim 1 wherein forming the insulating film overlying the ZnO nanotips includes forming the insulating film from a material selected from the group consisting of spin-on polystyrene and polymers; and,
wherein etching the insulating film includes etching the insulating film using an 03 plasma.

11. The method of claim 1 wherein forming the insulating film overlying the ZnO nanotips includes forming the insulating film from spin-on glass (SOG); and,
wherein etching the insulating film includes etching the SOG using a process selected from the group consisting of wet etching and dry etching.

12. The method of claim 1 further comprising:
forming a p-type material interposed between the exposed ZnO nanotip tops and the transparent electrode, selected from the group consisting of poly(3,4-ethylenedioxythiophene (PEDOT), SrCuO, Cu2O, ZnO:N, ZnO:As, and ZnO:P.

13. The method of claim 1 wherein forming the transparent electrode includes forming the transparent electrode from a material selected from the group consisting of a thin layer of ITO, ZnO:Al, and Au.

14. The method of claim 1 wherein forming the bottom contact and the seed layer includes forming both layers from a ZnO:Al layer overlying the Si substrate.

15. The method of claim 14 further comprising:
using an ALD process, forming an insulator interposed between the ZnO:Al layer and the ZnO nanotips, from a material selected from the group consisting of Al₂O₃ and HfO₂.

16. A ZnO nanotip electroluminescence (EL) device on silicon (Si) substrate, the EL device comprising:
a Si substrate;
a bottom contact overlying the Si substrate;
a seed layer overlying the bottom contact;
ZnO nanotips with tops, overlying the seed layer;
an insulating film overlying the ZnO nanotips, having a top surface with exposed ZnO nanotip tops; and,
a transparent top electrode overlying the exposed ZnO nanotip tops.

17. The EL device of claim 16 wherein the bottom contact includes an n+ layer of Si overlying the Si substrate.

18. The EL device of claim 16 wherein the seed layer is a material selected from the group consisting of ZnO and ZnO:Al.

19. The EL device of claim 16 wherein the seed layer is crystallized.

20. The EL device of claim 16 further comprising:
a coating over the ZnO nanotips, selected from the group comprising Al₂O₃ and HfO₂.

21. The EL device of claim 16 wherein the insulating film is a material selected from the group consisting of spin-on polystyrene, spin-on glass, and polymers.

22. The EL device of claim 16 further comprising:
a p-type material interposed between the exposed ZnO nanotip tops and the transparent electrode, selected from the group consisting of poly(3,4-ethylenedioxythiophene) (PEDOT), SrCuO, Cu2O, ZnO:N, ZnO:As, and ZnO:P.

23. The EL device of claim 16 wherein the transparent electrode is a material selected from the group consisting of a thin layer of ITO, ZnO:Al, and Au.

24. The EL device of claim 16 wherein the bottom contact and the seed layer are both a ZnO:Al layer overlying the Si substrate.

25. The EL device of claim 24 further comprising:
an insulator interposed between the ZnO:Al layer and the ZnO nanotips, made from a material selected from the group consisting of Al₂O₃ and HfO₂.
